(19) United States
(12) Patent Application Publication
(10) Pub. No.: US 2002/0048203 A1
(43) Pub. Date: Apr. 25, 2002

(54) Extending total write cycles of non-volatile memory for rolling codes

(76) Inventors: Patrick M. Findling, Lake Orion, MI (US); Yeung C. Chan, Madison Heights, MI (US); Vitally Selektor, Troy, MI (US); Saniava Dash, Rochester Hills, MI (US)

Correspondence Address: LAURA M. SLENZAK, SIEMENS CORPORATION, 186 WOOD AVENUE SOUTH, ISELIN, NJ, 08830, US

(21) Appl. No.: 09/982,042

(22) Filed: Oct. 18, 2001

Related U.S. Application Data
(60) Provisional application No. 60/241,943, filed on Oct. 19, 2000.

(51) Int. Cl. G11C 29/00

(52) U.S. Cl. 365/200

(57) ABSTRACT

A method of writing to a non-volatile memory used in rolling code applications includes the steps of initializing multiple bit locations for first and second non-volatile memory locations to provide a first and second value. The second non-volatile memory location initializes all bits except for one to a common state. The first and second values combine according to a predetermined algorithm to obtain a total value used by the rolling code application. The total value is incremented by shifting the one bit not in a common state in the second non-volatile memory location such that only the bit that is being changed back to a common state and the bit being changed to the non-common state experience a write cycle in order to increase the number of total write cycles reliable available for the rolling code application.

This application claims priority to the provisional application Ser. No. 60/241,943 filed on Oct. 19, 2000.

### BACKGROUND OF THE INVENTION

This invention relates to a method of writing to a non-volatile memory to extend the number of useful write cycles for applications in which a value stored in memory is incremented by a fixed amount such as in a rolling code used to communicate between a key fob and a motor vehicle.

Non-volatile memory devices maintain a state of memory in the absence of electrical power. A type of non-volatile memory known as an electrically erasable and programmable read-only memory (EEPROM) stores information used in keyless entry systems. One type of keyless entry system saves a value in the non-volatile memory that is incremented by a fixed amount after every actuation of a transmitter commonly referred to as a key fob. Incrementing the value changes the code according to a predetermined algorithm thereby preventing a thief from recording a code and using the recoded code later to gain access. This method of incrementing a code is known in the art as a rolling code and is commonly utilized in automotive keyless entry systems and garage door opener systems.

Typically, a non-volatile memory device includes multiple memory locations, known as bytes that are composed of multiple bits. Each time the value is incremented by transmission from the key fob that value is stored in the next available memory location. This continues until all of the memory locations are full. The system then starts over by writing over the first location. Each time a value is changed, all of the bits in a particular memory location experience a write cycle. By writing to the entire value, all of the bits in a particular memory location experience a write cycle, regardless of whether or not the value stored in that specific bit location has changed. Further, this method uses an entire set of bits to store a value, therefore if four values are stored and each requires 32 bits, than 128 bits are required.

Non-volatile memory devices have only a limited number of write cycles until the memory device will no longer reliably store and maintain values. Unreliable memory of values used for rolling codes can result in an inability for a keyless entry system to operate. Non-volatile memory devices are currently available at rated life cycles between 10,000 and 100,000 cycles. The cost of each memory devices directly relates to the amount of available write cycles.

There is a need for a method of writing to a non-volatile memory that extends the number of reliable write cycles without resorting to higher cost memory devices or the addition of substantially more memory.

### SUMMARY OF THE INVENTION

An embodiment disclosed in this application is a method of writing to a non-volatile memory that increases the number of write cycles for applications in which a value is incremented by a fixed amount without using significantly more memory.

The method disclosed utilizes first and second non-volatile memory locations that include multiple bit locations. The structure of the non-volatile memory locations is such that each bit contained in each of the first and second memory locations is independent of the other bits. This method uses this structure to increase the total useful write cycles for the system. Prior art methods of writing to a non-volatile memory include writing each of the multiple bit locations upon any change in value of any one bit, such that a write cycle was used even for bits not changing value. In the method of the subject application, bits that are not changing value are not overwritten and therefore the number of useful write cycles is substantially increased.

The method includes the steps of initializing a first and second non-volatile memory location to first and second values. Bits located in the first memory location are initialized to a common state. The state of a bit refers to a binary state of either an erased value or a non-erased value. The erased value can be represented by a “0” or a “1” depending on the specific structure of the memory device. The second value is initialized such that all of the bits are at an erased value except for one. For illustrative purposes in this application the erased value will be represented by “0”. The bits in the second memory location are therefore initialized to an erased value except for one bit. The one non-erased bit is preferably positioned at the least significant bit location available in the second memory location. The values stored in the first and second memory locations combine to provide a total value. The total value is the value used for the rolling code. Combination of the first and the second value occurs according to a predetermined algorithm. The total value is incremented each time the transmitter actuates to change the rolling code.

The incrementing of the total value is accomplished by incrementing the second value stored in the second memory location. The second value is incremented by shifting the non-erased bit one bit location toward the most significant bit location.

This shift is known in the art as a logical shift to the left, or as a “walking bit”. The bits in the second memory location are controlled independently such that shifting of the non-erased bit requires only that one bit experiences a write cycle. Once the non-erased bit has shifted off the end of the second memory location the first memory location is incremented by changing the least significant bit to a non-erased state. The second memory is then rolled over or set back to the initial value such that the least significant value is set to a non-erased value.

The result of this method of writing to a non-volatile memory is that each bit experiences a write cycle once every time the second memory location rolls over. The method of this invention increases the total number of write cycles for a non-volatile memory used for a rolling code application without an increase in the amount or cost of memory.

### BRIEF DESCRIPTION OF THE DRAWINGS

The various features and advantages of this invention will become apparent to those skilled in the art from the following detailed description of the currently preferred embodiment. The drawings that accompany the detailed description can be briefly described as follows:

FIG. 1 is a schematic illustration of a keyless entry system for an automobile;

FIG. 2 is a schematic illustration of first and second memory locations; and

FIG. 3 is a flow chart illustrating the steps of writing to the non-volatile memory locations.

### DETAILED DESCRIPTION OF THE PREFERRED EMBODIMENT

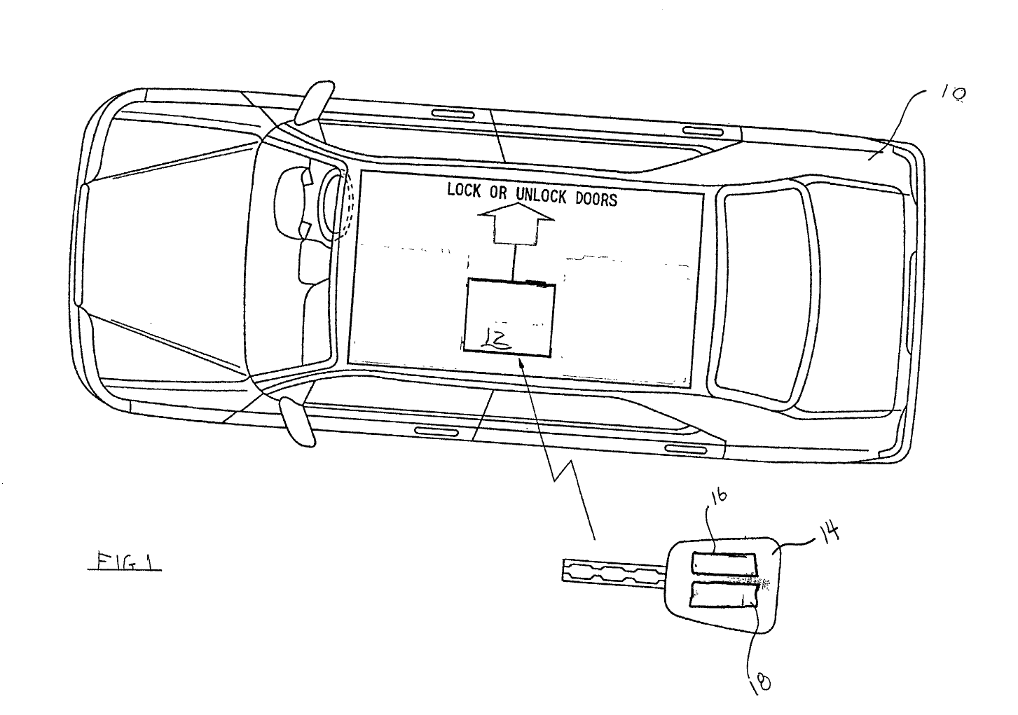

Referring to the Figures, wherein like numerals indicate like or corresponding parts throughout the several views, a method of writing to a non-volatile memory is disclosed. FIG. 1 is a schematic view of an automobile 10 with a keyless entry system 12 actuated by a remote transmitter or key fob 14. The key fob 14 includes two memory locations 16, 18 that store a value used by the system 12 to increment a code by a fixed amount. Such codes that increment are commonly referred to as a rolling code. Although the figures illustrate the use of the rolling code stored in a key fob, other applications that utilize a rolling code can benefit from application of this invention.

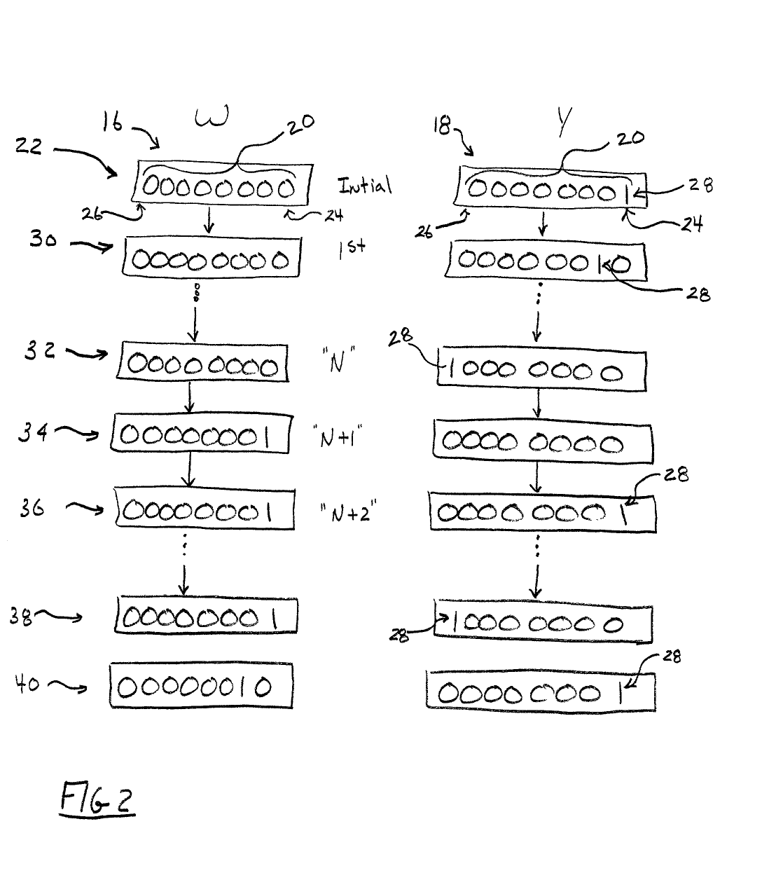

Fig. 2 is a schematic representation of the first and second non-volatile memory locations 16,18. Each memory location includes multiple bit locations 20 with bits in either an erased or a non-erased state. The erased state of a bit location is represented by a “0” and the non-erased state is represented by a “1”. One skilled in the art will recognize that some memory devices may include erase values that are indicated by “1” and non-erased values of “0” and that the method of this invention is applicable to such types of memory devices. The memory locations shown in FIG. 2 include eight bit locations, however memory devices having any number of bit locations as known in the art would also benefit from the method of this invention.

A memory device is rated for a finite number of write cycles. A write cycle includes the erasing and subsequent writing to of a bit location. A bit location that is changed from a non-erased value to an erased value only experiences half of a write cycle. A subsequent change of the bit location back to a non-erased value completes the write cycle. Note that the two parts of a write cycle do not need to occur at the same time. The erase portion of the write cycle can occur days from the write portion of the write cycle. This characteristic of a non-volatile memory device is known to one skilled in the art. The finite number of write cycles is applicable to each bit location independent of the surrounding bits. This structure of the memory device is favorably utilized by this method to substantially increase the number of useful write cycles for any given memory device.

As shown in FIG. 2, the first and second memory locations 16, 18 are initialized to an initial value. The initialized values of both the first and second values are indicated at 22. The first memory location 16 is initialized such that the bits 20 are all in a common erased state. Typically, memory devices from the manufacturer are provided in the erased state such that a write cycle is not utilized to initialize each bit to the erased value. As appreciated, some memory devices may be initialized from the manufacture in a non-erased state. For such memory devices, the initialized value of the first memory location would by the non-erased state.

The second memory location is initialized such that all of the bits except for one are in an erased state and one bit is provided in the non-erased state. Preferably, the bit in the non-erased state occupies a least significant bit location 24. Although preferably the non-erased bit is located at the least significant bit location it is within the contemplation of this invention that the initial non-erased bit location can be positioned anywhere within the memory, such as starting at the most significant bit location 26.

Bits within the first memory location 16 represent a first value and bits within the second memory location 18 represent a second value. The combination of first and second values comprise a total value used by the rolling code system 12. The combination of the first and second values is represented in simplest mathematical terms as:

V=W+f(Y)

where V is the total value used for the rolling code;

W is the first value stored in the first memory location

Y is the second value stored in the second memory location; and

f is a function needed to translate Y into a value to add to W.

The simplest function to translate Y is defined by the mathematical expression

f(Y)=A*(bit n)

where Y is the second value stored in the second memory location;

f is the function to translate Y; and

A is the amount that W increments; and

bit n is the bit location designation within the second memory location.

The amount that the second value or “W” is incremented is preferably one bit location, however W may be incremented by other values depending on requirements of the rolling code system.

Further, combination of the first and second values W, Y can include designating the first value W in the first memory device 16 as the most significant bits and the second value Y in the second memory device 18 as the least significant bits such that a binary OR calculation is achieved rather than addition. As appreciated, any method of combining the values stored in the first and second memory locations 16, 18 are within the contemplation of this invention and such alternate methods would also benefit from the extended number of write cycles provided by this method.

Upon activation of the transmitter 14, the system requires that the total value “V” increment to advance the rolling code. The total value V increments by changing the value Y of the second memory location 18. Referring to the next row indicated at 30 in FIG. 2, the non-erased bit 28 in the second memory location 18 is shifted one bit location 20 toward the most significant bit location 26. The non-erased bit 28 is preferably shifted by erasing the second memory location 18 and writing a new value of Y. The bit locations 20 contained in the second memory location 18 that are not changing state do not experience a write cycle because they are already in the proper state. In this way, the total value V can be incremented by writing to one bit location 20 contained in the second memory location 18. The non-erased bit 28 shifts from the least significant bit location 26 to the most significant bit location 28 to progressively increment the total value V.

Row 32 indicated in FIG. 2, represents the state of bits 20 within the two memory locations 16, 18 at an increment “N” where the non-erased bit 28 has shifted to the most significant bit location 26. The subsequent increment, indicated at row 34, shifts the non-eased bit 28 off the second memory location 18, and is shown as all of the bit locations containing an erased value. The first memory location 16 increments by switching the least significant bit location 24 to a non-erased state.

This method provides that each bit location will experience a write cycle once each time the non-erased bit 28 is cycled through the bits of the second memory location. In other words for a memory device including “Z” number of bit locations each bit will experience a write cycle once every Z increments. The first memory location increments as if the second memory location includes Z+1 bit locations to account for the non-erased bit shifting off the second memory location.

Referring to row 36, after the first memory location has incremented by writing to or changing the state of the least significant bit location, the second memory location 18 is set to an initial state as shown in row 22. The first memory location further increments, as shown in rows 38 and 40, as the non-erased bit 28 cycles through the bit locations 20 of the second memory location 18. Note that the non-erased value in the first memory location 16 moves one bit location toward the most significant bit location for each Z increments of the second memory location 18.

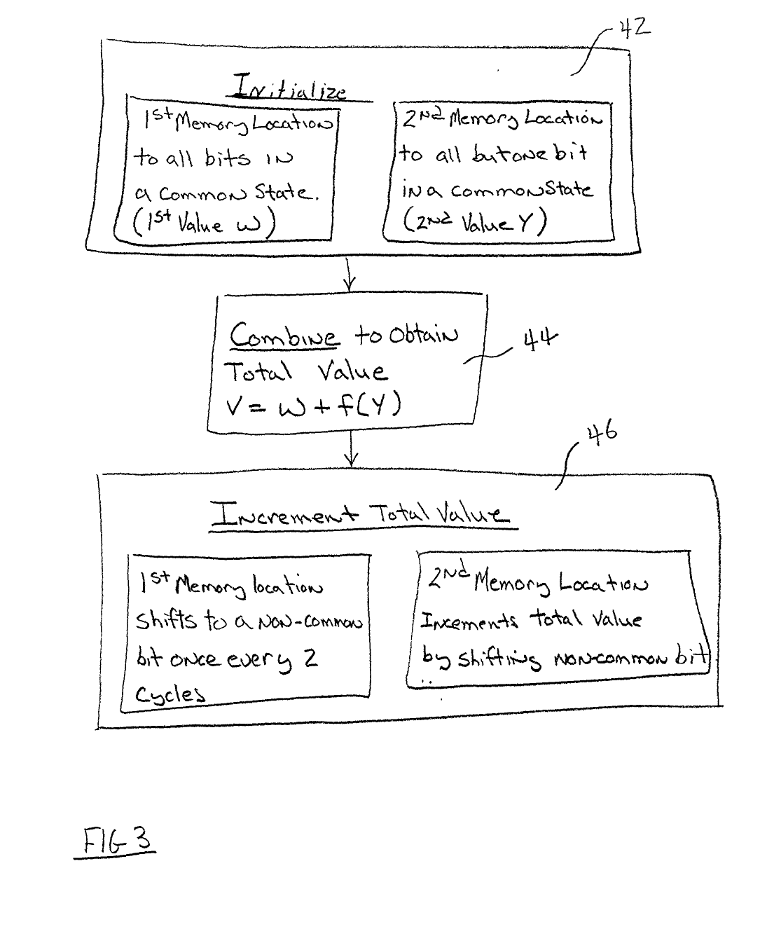

Referring to FIG. 3, a flow chart of the method of incrementing a non-volatile memory is shown. The first step in the method indicated at 42 includes the step of initializing the first and second memory locations 16,18. This step includes the sub step of initializing the first memory location 16 to an entirely common state. The common state can be the state in which the memory device arrives from the manufacturer. The second memory location 18 is initialized such that all of the memory locations are a common state, but for one bit location. Preferably, the common state for the second memory location 18 is the erased state.

The next step on the method indicated at 44 includes combining the value Y within the second memory location 18 with the value contained in the first memory location W to obtain a total value V. The total value V is the value that is utilized by the rolling code system to increment the code after each actuation of the transmitter 14. The combination of the first and second values W, Y can be of any type known to one knowledgeable in the art compatible with the rolling code system.

Upon actuation of the transmitter 14, the total value V is incremented. Note that the transmitter 14 is only one means of triggering a change of the total value V. A worker in the art will recognize that the use of a rolling code system is not limited to use as a keyless entry system 12 for an automobile 10, and that other uses such as garage door opening devices would benefit from the method of this invention. Further, other systems may use devices other than a transmitter to trigger actuation of the system to change the value of the rolling code and thereby the total value, and would also benefit form the method of this invention.

Incrementing of the total value V is indicated at 46 and includes the sub step of incrementing the second memory location 18 such that the non-common bit 28 is shifted one bit from the least significant bit location 24 toward the most significant bit location 26. Preferably the non-common or non-erased bit 28 is initially located at the least significant bit location 24, however it is within the contemplation of this invention to initialize the non-erased bit 28 at the most significant bit location 26 and shift the non-erased bit 28 toward the least significant bit location 24.

The shift of the non-common or non-erased bit 28 is further defined by erasing the bits 20 in the second memory location 18 and writing a new value Y. Because each bit in a memory location is independently controllable, only the bits that are actually changing state experience a write cycle.

The total value V is incremented by incrementing only the second memory location 18 until the non-erased bit 28 in the second memory location 18 shifts such that all of the bits 20 are set to an erased state. This condition is described as the non-common bit being “shifted off” of the second memory location. Only when the non-erased bit 28 has shifted off the second memory location 18 such that all of the bit locations 20 are in a common or erased state does the first memory location 16 increment. The first memory location 16 increments such that the least significant bit location 24 is changed from an erased state to a non-erased state. Once the first memory location 16 has been incremented, the second memory location 18 is set back to the initial value where the least significant bit location 24 is set to the non-erased state. This process continually repeats such that for each increment of the total value only one bit experiences a write cycle. By only writing one bit location during each actuation, the reliable life of a memory location is substantially increased.

The foregoing description is exemplary and not just a material specification. The invention has been described in an illustrative manner, and should be understood that the terminology used is intended to be in the nature of words of description rather than of limitation. Many modifications and variations of the present invention are possible in light of the above teachings. The preferred embodiments of this invention have been disclosed, however, one of ordinary skill in the art would recognize that certain modifications are within the scope of this invention. It is understood that within the scope of the appended claims, the invention may be practiced otherwise than as specifically described. For that reason the following claims should be studied to determine the true scope and content of this invention.

What is claimed is:

1. A method of writing to a non-volatile memory including a total value incremented by a fixed amount, said method comprising the steps of;
a. initializing a first non-volatile memory location including multiple bits corresponding to specific bit locations such that all of said bits are set to a common state representing a first value;
b. initializing a second non-volatile memory location including multiple bits corresponding to specific bit locations such that all of said bits except for one are set to a common state representing a second value;
c. combining said first and second values to obtain the total value; and
d. incrementing the total value by a fixed amount by changing said second value of said second non-volatile memory location by shifting which of said bit locations includes said bit not set to said common state.

2. The method of claim 1, further including the step of incrementing the total value by changing said first value of said first memory location by incrementing one bit location in response to said second memory location being incremented through all of said multiple bit locations.

3. The method of claim 2, wherein said step of incrementing the total value is further defined by combining a second value equal to one plus a maximum number of bit locations present in said second non-volatile memory location to said first value, and further including the step of setting said second value back to said initialized value.

4. The method of claim 1, wherein said bit not set to said common state in said second non-volatile memory location is a least significant bit.

5. The method of claim 1, wherein said bit not set to said common state in said second non-volatile memory location is a most significant bit.

6. The method of claim 1, wherein said common state is an erased state.

7. The method of claim 4, wherein step d is further defined by shifting said one bit not set to said common state one bit location toward a most significant bit.

8. The method of claim 6, wherein said shifting of said one bit location is further defined by erasing said bits of said second non-volatile memory location and writing a new value such that said bits previously in said common state and remaining in a common state for said incremented value do not experience a write cycle.

9. The method of claim 1, wherein each of multiple bit locations of said first and second non-volatile memory locations are independently controllable.

10. The method of claim 1, wherein said step c is further defined by translating said second value by way of a preset algorithm before combining said second value with said first value.

11. The method of claim 1, wherein said combining steps is further defined by said first value representing most significant bits and said second value representing a least significant bit such that said combination of said first and second values are a binary “OR” calculation.

12. The method of claim 1, wherein said total value is used to encrypt a transmission for a remote keyless entry system.

13. The method of claim 15, wherein said first and second non-volatile memory locations are located within a transmitter of said remote keyless entry system, such that said first and second values provide for the storage of a rolling code.

14. A non-volatile memory device for use in a rolling code security system comprising:
first and second non-volatile memory devices for storing a total value used to form a coded signal that is incremented by a fixed amount;
said first and second non-volatile memory devices including multiple bit locations that represent first and second values, said first and second values combined to form said total value, and only one of said multiple bit locations completes a write cycle each increment of said total value.

15. The device of claim 1, wherein said first non-volatile memory device includes said first value and said second non-volatile memory device includes said second value.

16. The device of claim 2, wherein a number of said multiple bit locations are disposed within said second non-volatile memory location and said total value is incremented by shifting which of said multiple bit location disposed within said second non-volatile memory location are in a non-common state.
